(19) United States
(12) Patent Application Publication
(10) Pub. No.: US 2010/0289379 A1
(43) Pub. Date: Nov. 18, 2010

(54) SURFACE ACOUSTIC WAVE (SAW) DEVICE

(75) Inventors: Takuya Owaki, Chigasaki-shi (JP); Takao Morita, Fujisawa-shi (JP)

Correspondence Address: OLIFF & BERRIDGE, PLC, P.O. BOX 320850, ALEXANDRIA, VA, 22320-4850, US

(73) Assignee: EPSON TOYOCOM CORPORATION, Tokyo (JP)

(21) Appl. No.: 12/848,475

(22) Filed: Aug. 2, 2010

Related U.S. Application Data
(63) Continuation of application No. 11/922,410, filed on Dec. 18, 2007, now abandoned.

(30) Foreign Application Priority Data
Jun. 30, 2005 (JP) 2005-192660

(51) Int. Cl. H01L 41/047; H01L 41/04; H01L 41/08

(52) U.S. Cl. 310/313 A

(57) ABSTRACT

[Problem] In a SAW device using a SH-wave type surface acoustic wave, obtain a means to improve the Q factor.

[Means to Solve the Problem] A surface acoustic wave (SAW) device includes a rotated Y-cut quartz crystal substrate where a cut angle “θ” is set in −64.0°<θ<−49.3° with a crystalline Z-axis, an interdigital transducer (IDT) electrode formed on the quartz crystal substrate along a perpendicular direction to a crystalline Z-axis (a Z′-axis direction) of the quartz crystal substrate and grating reflectors disposed at both sides of the IDT, wherein a normalized electrode film thickness “H/λ” which is a film thickness “H” of the IDT electrode normalized by an electrode period “λ” of the IDT electrode is 0.04≦H/λ≦0.12, and a normalized crossing width “W/λ” which is a crossing width “W” of the IDT electrode normalized by the electrode period “λ” is set in the range of 20≦W/λ≦50.

This is a Continuation of Application No. 11/922,410 filed Dec. 18, 2007, which in turn is a national phase of PCT/JP2006/313365 filed Jun. 28, 2006, which claims the benefit of Japanese Patent Application No. 2005-192660 filed Jun. 30, 2005. The disclosures of the prior applications are hereby incorporated by reference herein in their entirety.

### TECHNICAL FIELD

The present invention relates to a Surface Acoustic Wave (SAW) device and particularly relates to improvement in Q-factor of the SAW device.

### BACKGROUND

In recent years, Surface Acoustic Wave (hereinafter referred to as SAW) devices have been widely used as components for mobile communication terminals, local area network (LAN) and the like because of their excellent features including high performance, small in size and mass productive. Particularly a SAW device utilizing a Rayleigh wave (a (P+SV) wave) that propagates a ST-cut quartz crystal substrate in an X-axis direction has been widely used (the ST-cut quartz crystal substrate is a quartz crystal substrate having a plane obtained by rotating a XZ-plane (Y-plane) counterclockwise from the crystalline Z-axis by 42.75° around the crystalline X-axis). Though the first-order temperature coefficient of the above-mentioned ST-cut quartz crystal SAW device is zero, the second-order temperature coefficient is −0.034 ppm/° C², which is relatively large. This can be a disadvantage that the amount of the fluctuation in the frequency becomes large when the operating temperature range is expanded.

Meirion Lewis, “Surface Skimming Bulk Wave, SSBW”, IEEE Ultrasonics Symp. Proc., pp.744-752 (1977) and JP-B-62-016050 disclose SAW devices that can overcome the above-mentioned disadvantage. Referring to FIG. 3(a), a cut angle “θ” of a rotated Y-cut crystal quartz substrate is set at about −50° rotated counterclockwise from the crystalline Z axis (substrate axes after the rotation are respectively X axis, Y′ axis and Z′ axis), and the SAW device is a SH wave type SAW device that utilizes the SH wave propagating in a perpendicular direction (Z′-axis direction) with respect to the crystalline X-axis. When this cut angle “θ” is expressed in Eular angle, it can be written as (0°, θ+90°, 90°)=(0°, 40°, 90°). FIG. 3(b) shows a SH-wave type SAW resonator having an interdigital transducer (IDT) 12 formed along the Z′ axis on a principal plane of a rotated Y-cut quartz crystal substrate 11 and reflectors 13a, 13b disposed at both sides of the IDT. In the SAW device, the SH-wave type surface acoustic wave propagating just below the surface of the piezoelectric substrate is excited by the IDT 12, and the vibration energy is confined right under the electrodes (12, 13a, 13b). The frequency-temperature characteristic of the SH-wave type SAW device is plotted as a cubic curve and a fine frequency-temperature characteristic can be obtained in a wide temperature range.

However the SH-wave type SAW generally propagates inside the substrate so that its reflection efficiency by the grating reflector is low compared with that of a SAW device utilizing a SAW propagating along the surface of the piezoelectric substrate such as the Rayleigh wave excited in a ST-cut quartz crystal. For this reason, it was difficult to realize a small-sized and high-Q SH-wave type SAW device.

In order to solve the above-mentioned problem, JP-B-01-034411 discloses a SAW resonator utilizing the SH-wave type SAW propagating in the Z′-axis direction of the rotated Y-cut crystal quartz substrate 11 whose cut angle “θ” is −50° as shown in FIG. 4. The SAW resonator is a so-called multiple-pairs IDT electrode type SAW resonator in which an IDT 14 having 800±200 pairs of electrodes is formed. The multiple-pairs IDT electrode type SAW resonator confines the SH-wave type SAW energy only by the reflection by the electrode fingers of the IDT electrode 14 and without using the grating reflector in order to obtain a high Q factor.

However the multiple-pairs IDT electrode type SAW resonator cannot confine the energy as efficiently as the Rayleigh-wave type SAW resonator which uses a grating reflector can. Accordingly the number of the pairs of the IDT electrodes which is required to obtain the high level of the Q factor becomes as large as 800±200. This means that the substrate size exceeds that of the ST-cut quartz crystal SAW resonator and consequently the device size becomes large. In this sense the recent request of downsizing cannot be realized.

According to the SAW resonator disclosed in JP-B-01-034411, it is written that the level of the Q factor can be risen by setting the film thickness of the electrode 2%λ or larger and preferably equal to or smaller than 4%λ where “λ” is an electrode period (wavelength) of the SH-wave type SAW which is excited by the IDT electrode. In a case where the resonance frequency is 200 MHz for example, the Q factor reaches the highest value around the normalized electrode-film thickness of 4%λ. However the highest value of the Q factor is about the same as that of the ST-cut quartz crystal SAW resonator. This is presumably caused by a low reflection efficiency because the SH-wave type SAWs are not sufficiently accumulated on the surface of the piezoelectric substrate where the normalized electrode-film thickness lies in the range of 2-4% λ and the higher Q factor cannot be obtained.

Considering the above-mentioned problem, the inventor demonstrated in Japanese Patent Application No. 2004-108608 that a high Q factor and a fine second-order temperature coefficient can be obtained by setting a rotated angle “θ” of the Y-cut quartz substrate within a range of −64.0°<θ<−49.3° counterclockwise with the crystalline Z-axis, using the SH-wave type SAW propagating in the direction of 90°±5° with the crystalline X-axis, and setting a normalized electrode film thickness “H/λ” in 0.04<H/λ<0.12.

FIG. 5 shows a measurement result of the Q factor of the SAW resonator where the normalized electrode film thickness “H/λ” is changed from 0.03 to 0.15. Here the resonance frequency of the SAW resonator is 315 MHz, and the SAW resonator has a −51° rotated Y-cut 90° X propagation quartz crystal substrate as the quartz crystal substrate 11 shown in FIG. 3(b), 100 pairs of the electrodes in the IDT electrode 12, the grating reflectors 13a, 13b each of which has 100 fingers. It can be understood from FIG. 5 that the Q factor increases sharply as the normalized electrode film thickness “H/λ” becomes larger starting from 0.03, the Q factor reaches the maximum value around the point where “H/λ” is 0.06 and the Q factor decreases monotonically as the normalized electrode film thickness “H/λ” becomes larger. In other words, the graph shows that a Q factor higher than that of the ST-cut quartz crystal resonator (=15,000) can be obtained by setting the normalized electrode film thickness “H/λ” in the range of 0.04<H/λ<0.12. Moreover, it should be understood from the graph that the Q factor higher than 20,000 can be obtained by setting the normalized electrode film thickness “H/λ” in the range of 0.05<H/λ<0.10.

FIG. 6 shows the relation between the normalized electrode film thickness “H/λ” and the second-order temperature coefficient in the SAW resonator where the parameters are the same as the ones used in FIG. 5. FIG. 6 shows that a better second-order temperature coefficient than that of the ST-cut crystal quartz resonator (−0.034 ppm/° C²) can be obtained by setting the normalized electrode film thickness “H/λ” in the range of 0.04<H/λ<0.12 where the high Q factor is obtained.

Moreover, Japanese Patent Application No. 2004-108608 discloses that the peak temperature of the frequency-temperature characteristic can be set in a practical range of 0-70° C. when the cut angle of the rotated Y-cut quartz substrate is set in −61.4°<θ<−51.4° counterclockwise with respect to the crystalline Z-axis.

A prototype of a filter in which two first-second order longitudinal coupling double-mode SAW filters (hereinafter referred to as L-DMS filter) are coupled in cascade was fabricated according to Japanese Patent Application No. 2004-108608. Referring to FIG. 7 which is a plan view of the L-DMS filter, an L-DMS filter F1 has IDT electrodes 22, 23 that are disposed adjacently each other on a principal plane of a piezoelectric substrate 21 along the Z′-axis direction and grating reflectors 24a, 24b disposed at the sides of the IDT electrodes 22, 23. The IDT electrodes 22, 23 respectively consist of a pair of interdigital electrodes having a plurality of electrode fingers. In the same manner as the first L-DMS filter F1, a second L-DMS filter F2 having IDT electrodes 22′, 23′ and grating reflectors 24a′, 24b′ is formed on the same piezoelectric substrate 21. Bus bars that are situated about the center of the substrate and extended from the first L-DMS filter F1 and the second L-DMS filter F2 respectively are coupled each other through a lead electrode. In this way, the two-stage cascade-coupling type L-DMS filter was fabricated.

The dual cascade-coupling type L-DMS filter described with reference to FIG. 7 was then formed on a quartz crystal substrate having the cut angle “θ” of −52°. A center frequency is 315 MHz, the number of the electrode pairs in each of the IDT electrodes 22, 23 (22′, 23′) is 45 respectively, the number of the electrodes in each of the grating reflector 24a, 24b (24a′, 24b′) is 110, the normalized electrode film thickness “H/λ” is 6%, a crossing width “W” is 10λ and 20λ (where “λ” is an electrode period). A characteristic of the filter was measured. The measured pass-band characteristic is plotted in FIG. 8. In FIG. 8, the characteristic where the crossing width “W” is 20λ is shown in the solid line and the characteristic where the crossing width “W” is 10λ is shown in the broken line.

Though a high Q factor and a fine second-order temperature coefficient can be obtained by setting the normalized film thickness appropriately as described above and the peak temperature in the quadratic curve of the frequency-temperature characteristic can be set in the practical temperature range, there still is a problem that an insertion loss of the filter largely varies depending on the crossing width “W”. In other words the Q factor of the SAW resonator that forms the L-DMS filter fluctuates according to the crossing width “W”.

### DISCLOSURE OF THE INVENTION

A surface acoustic wave (SAW) device according to an aspect of the invention includes a rotated Y-cut quartz crystal substrate where a cut angle “θ” is set in −64.0°<θ<−49.3° with a crystalline Z-axis, at least one interdigital transducer (IDT) electrode formed on the quartz crystal substrate along a perpendicular direction to a crystalline Z-axis (a Z′-axis direction) of the quartz crystal substrate and grating reflectors disposed at both sides of the IDT, wherein a normalized electrode film thickness “H/λ” which is a film thickness “H” of the IDT electrode normalized by an electrode period “λ” of the IDT electrode is 0.04≦H/λ≦0.12, and a normalized crossing width “W/λ” which is a crossing width “W” of the IDT electrode normalized by the electrode period “λ” is set in the range of 20≦W/λ≦50.

In this case, the IDT electrode and the reflectors may be made of Al or an Al-based alloy.

In this case, the SAW device may be used for an oscillator or a module.

### BRIEF DESCRIPTION OF THE DRAWINGS

FIG. 1 is plan view of a SH-wave type SAW resonator which is an example of a SAW device according to the invention showing its structure schematically.

FIG. 2 is a graph showing a relation between a Q factor and a normalized crossing width “W/λ” of the SH-wave type SAW resonator.

FIG. 3(a) shows a cut angle where the SH-wave type SAW is excited, and FIG. 3 (b) is a plan view showing an electrode pattern of the SH-wave type SAW resonator.

FIG. 4 is a plan view of a multiple-pairs IDT electrode type SAW resonator.

FIG. 5 is a graph showing a relation between a Q factor and a normalized electrode film thickness “H/λ” of the SH-wave type SAW resonator.

FIG. 6 is a graph showing a relation between a Q factor and a second-order temperature coefficient of the SH-wave type SAW resonator.

FIG. 7 is a plan view of a two-stage cascade-coupling type L-DMS filter.

FIG. 8 is graph showing a pass-band characteristic of the two-stage cascade-coupling type L-DMS filter where a crossing width is 10λ and 20λ.

### DESCRIPTION OF THE PREFERRED EMBODIMENT

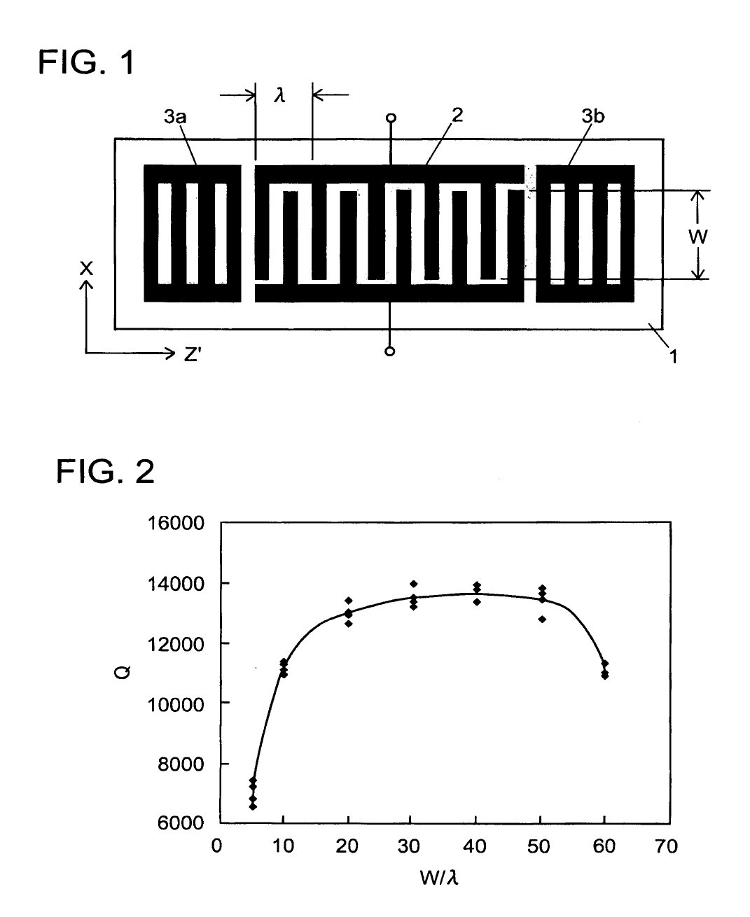

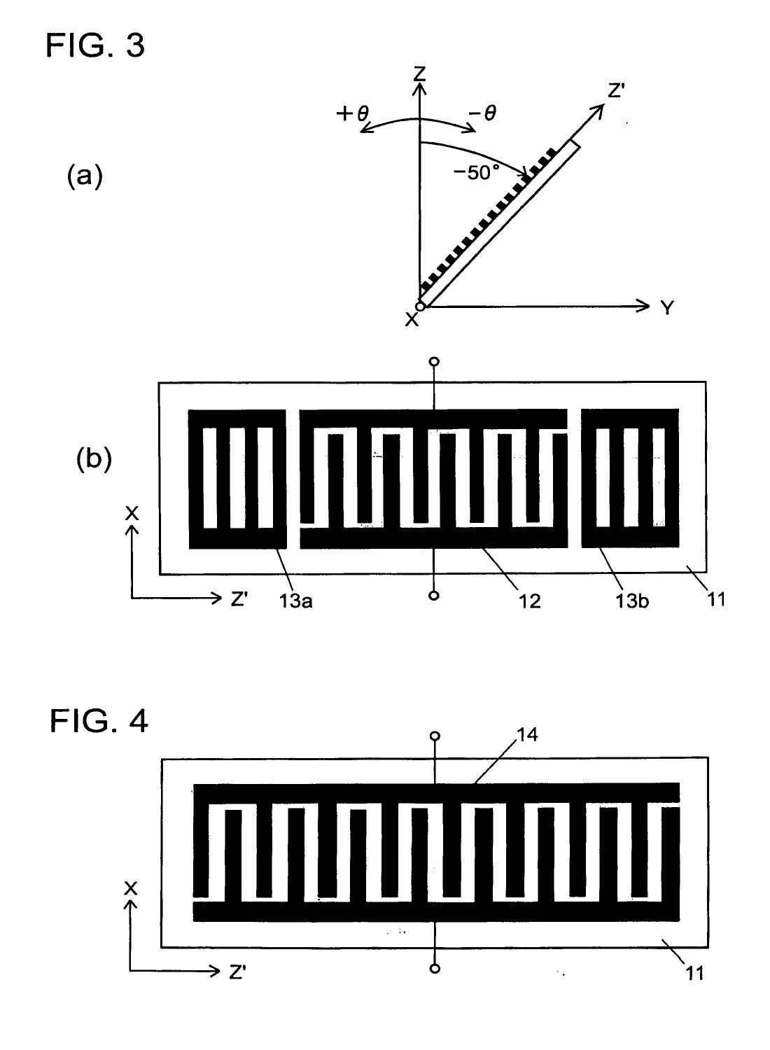

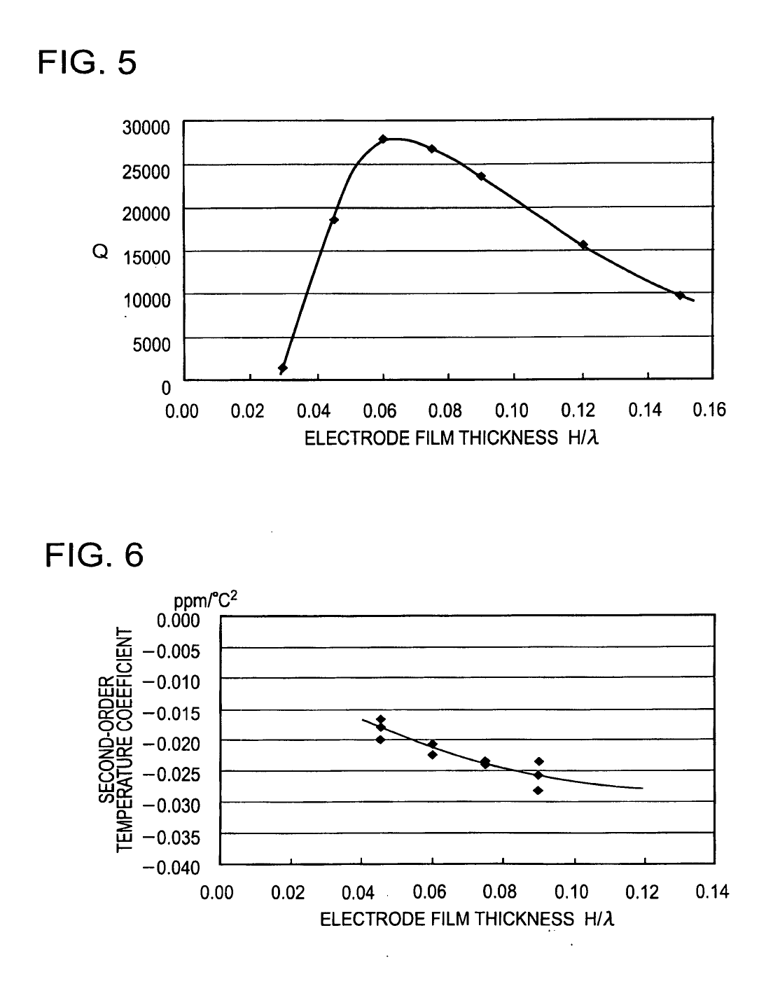

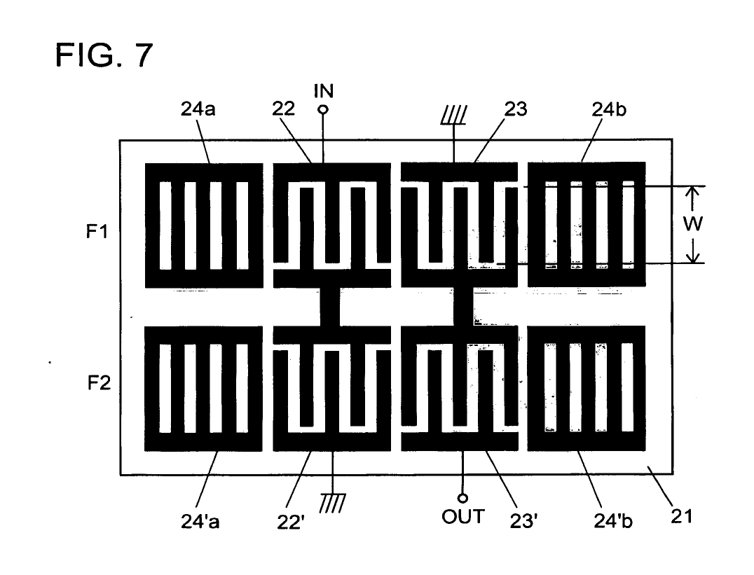

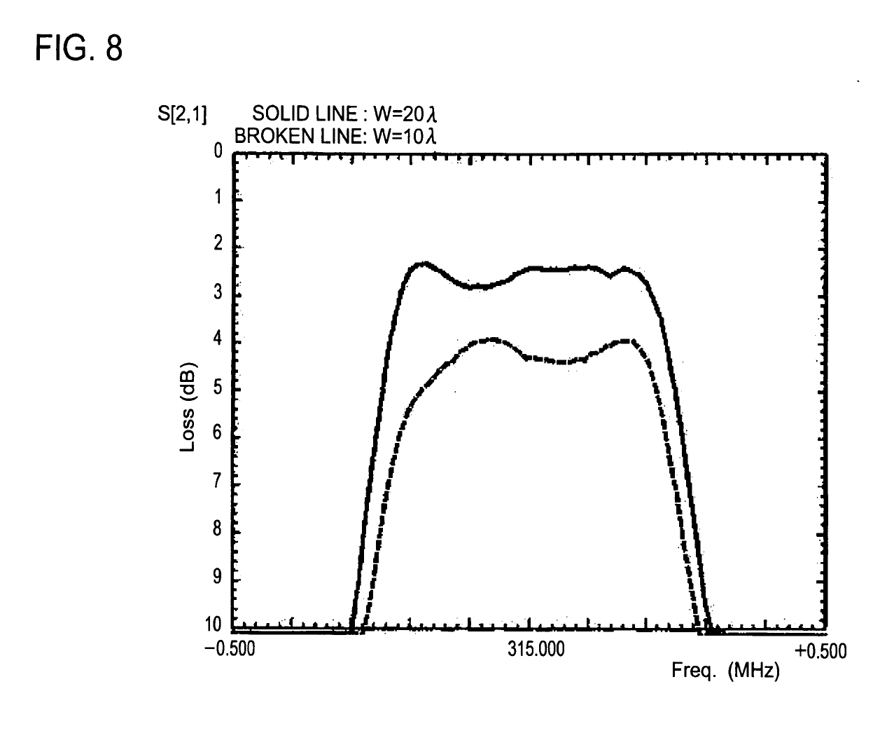

FIG. 1 is a plan view of a SH-wave type SAW resonator (hereinafter referred to as SAW resonator) which is an example of the SAW device according to an embodiment of the invention. The SAW resonator includes an IDT 2 that is arranged along the propagation direction (Z′-axis direction) of the SH-wave type surface acoustic wave on the principal plane of a piezoelectric substrate 1 and grating reflectors 3a, 3b disposed at the both sides of the IDT 2. The IDT 2 includes a pair of interdigitate electrodes having a plurality of electrode fingers interdigitating each other.

The piezoelectric substrate 1 is a Y-cut quartz crystal substrate where the cut angle “θ” is set in the range of −64.0°<θ<−49.3° counterclockwise with respect to the crystalline Z-axis, and the SH wave propagating in the perpendicular direction (Z′-axis direction) with respect to the crystalline X-axis is utilized. In order to make the peak temperature “Tp (° C.)” of the frequency-temperature characteristic of the SAW resonator set in the range of 0° C. ≦Tp≦+70° C., it is necessary to set the cut angle “θ” in the range of −61.4°<θ<−51.1° . As a material for forming electrodes, Al or Al-based alloy is adopted here. The Q factor higher than that of the ST-cut quartz crystal SAW can be obtained by setting the normalized electrode film thickness “H/λ” which is the film thickness normalized by the electrode period “λ” in the range of 0.04<H/λ<0.12, more preferably 0.05<H/λ<0.10.

Referring to FIG. 1, a prototype of the SAW resonator was fabricated by using the parameter “W/λ” which is the crossing width “W” of the IDT electrode 2 normalized by the electrode period “λ” (the wavelength of the excited SH-wave type surface acoustic wave) of the IDT electrode 2. The Q factor of the SAW was measured. Here, the SAW resonator was fabricated on the quartz crystal substrate whose cut angle “θ” is −52° , the frequency of the resonator was 620 MHz, the number of the electrode pairs in the IDT 2 was 100, the number of the electrodes in each of the grating reflector 3a, 3b was 120, the normalized electrode film thickness “H/λ” was 6%, and a line occupancy ratio “mr” (the electrode finger width/[the electrode finger width+the space between the two adjacent electrode fingers]) was 60%. As described above, the normalized crossing width “W/λ” was adopted as the parameter.

FIG. 2 is a graph showing the change in the Q factor of the SAW resonator as the normalized crossing width “W/λ” is changed. The horizontal axis of the graph is the normalized crossing width “W/λ” and the vertical axis of the graph is the Q factor. It can be understood from the graph shown in FIG. 2 that the Q factor deteriorates when the normalized crossing width “W/λ” is small because the vibration energy of the SH-type surface acoustic wave leaks from the IDT electrode into the quartz crystal substrate. On the other hand, when the normalized crossing width “W/λ” is large, the Q factor is also deteriorated because a high-order horizontal mode comes close to a main mode and ohmic loss of the IDT electrode increases. Considering these facts, it is found out that the normalized crossing width “W/λ” should be set in the range of 20<W/λ≦50 in order to obtain a high Q factor. It is possible to obtain a filter characteristic of low-loss by adopting the above-described resonator for the L-DMS filter.

Though the relation between the normalized crossing width “W/λ” and the Q factor in the SH-type SAW resonator has been mainly described in the above-embodiment, the invention is not limited to this but can be obviously applied to double-mode SAW filters using a first-second order longitudinal mode, a first-third order longitudinal mode and the like, longitudinal coupling multiple mode SAW filters using a longitudinal multiple mode, horizontal coupling multiple mode SAW filters using a horizontal multiple mode, and the like.

According to the SAW device of the invention, there is the advantage that the SAW device can have a highest Q value since the normalized crossing width “W/λ” normalized by the electrode period (wavelength) “λ” is set in the range of 20≦W/λ≦50.

Moreover, according the embodiment, there is another advantage that a practical SAW device can be fabricated because the electrode is formed of Al or Al-based alloy which is inexpensive and easily procured.

In addition, according the embodiment, a module, an oscillator and the like are formed by using the high-Q SAW devices so that the formed filter has a low insertion loss and the formed oscillator oscillates at a stable oscillation frequency.

As described above, according to the embodiments of the invention, it is possible to obtain a tuning fork type resonator element having a stable frequency-temperature characteristic by using a GaPO4 substrate which is cut out with a predetermined angle. Consequently it is possible to provide a small-sized tuning fork type resonator element having a stable frequency-temperature characteristic without adopting a complex mode coupling and a plurality of resonator elements.

1. A surface acoustic wave (SAW) device, comprising:
a rotated Y-cut quartz crystal substrate where a cut angle θ is set in −64.0°<θ<−49.3° with a crystalline Z-axis;
at least one interdigital transducer (IDT) electrode formed on the quartz crystal substrate along a perpendicular direction to a crystalline Z-axis of the quartz crystal substrate; and
grating reflectors disposed at both sides of the IDT,
wherein a normalized electrode film thickness H/λ which is a film thickness H of the IDT electrode normalized by an electrode period λ of the IDT electrode is 0.04≦H/λ≦0.12, and a normalized crossing width W/λ which is a crossing width W of the IDT electrode normalized by the electrode period λ is set in the range of 25≦W/λ≦50.

2. The SAW device according to claim 1, wherein the IDT electrode and the grating reflectors are made of Al or Al-based alloy.
